(19) United States
(12) Patent Application Publication
(10) Pub. No.: US 2009/0155948 A1
(43) Pub. Date: Jun. 18, 2009

(54) METHODS FOR MANUFACTURING CMOS COMPATIBLE BIO-SENSORS

(75) Inventors: Chen-Fu Lin, Kaohsiung County (TW); Hann-Huei Tsai, Tainan CIty (TW); Ying-Zong Juang, Tainan City (TW); Chin-Fong Chiu, Hsin-Chu City (TW)

Correspondence Address: BIRCH STEWART KOLASCH & BIRCH, PO BOX 747, FALLS CHURCH, VA, 22040-0747, US

(73) Assignee: National Applied Research Laboratories, Taipei (TW)

(21) Appl. No.: 11/959,282

(22) Filed: Dec. 18, 2007

(51) Int. Cl. H01L 21/8238

(52) U.S. Cl. 438/49; 257/E21.632

(57) ABSTRACT

A manufacture method for CMOS sensor, which comprise of steps such as: forming protection layer on a substrate having multiple device structural layers, then using first photo-resist layer as mask for etching to form patterned molecular sensing layer, then forming third photo resist layer and etching protection layer and substrate so as to remove partial substrate underneath the sensor structure.

### FIELD OF THE INVENTION

The present invention is related to a manufacture method for CMOS (Complementary Metal Oxide Semiconductor, CMOS) compatible sensor, it specifically relates to a manufacture method for CMOS compatible sensors for sensing Biological or ions concentration.

### BACKGROUND OF THE INVENTION

CMOS biosensor is to design biosensor with CMOS electronic device on the same chip, which is thus a process that can integrate biosensor and CMOS electronic device. However, the metal and other sensing film commonly used in the biosensor is not frequently used in general CMOS electronic device; therefore, some drawbacks are caused, for example, process design difficulty, process yield drop and process cost increase. For the prior art process of using CMOS device to prepare suspension structure, please refer to U.S. Pat. No. 6,396,368, which uses conductive metal, for example, aluminum copper, as a sacrificial layer. However, some drawbacks can be seen, for example, long etching time for lateral etching metal and the suspension height is fixed since the conductive metal is of fixed thickness. Therefore the movement stroke of suspension arm structure is then fixed and can not be utilized in several ways.

### SUMMARY OF THE INVENTION

One of the objectives of the present invention is to provide a manufacture method for CMOS biosensor, more specifically, a manufacture method for CMOS sensor having suspension arm structure which allows the formation of biosensor layer needed by the biosensor on silicon dioxide or conductive metal according to the need; in the same process, suspension arm structures of different thicknesses are made according to different design; moreover, process compatible with CMOS device is used to facilitate the electronic circuit integration.

Another objective of the present invention is to provide a manufacture method for CMOS Bio-sensor comprising of: providing a substrate having multiple device structural layer; forming a protection layer to cover the substrate and those device structures; forming a first patterned photo resist layer; performing a first etching process to etch the protection layer to a first etch stop; forming a patterned molecular sensing layer; forming a third patterned photo resist layer; and performing a second etching process to etch the protection layer and the substrate to a second etch stop so as to remove the substrate part underneath part of those sensor structures.

Yet another objective of the present invention is to provide a manufacture method for CMOS sensor wherein the method of forming the patterned molecular sensing layer comprising of: forming in sequence a second patterned photo resist layer and a molecular sensing layer on the substrate; and removing the second patterned photo resist layer and part of the molecular sensing layer on top of it.

Further another objective of the present invention is to provide a manufacturing method for CMOS sensor, wherein the method of forming the patterned molecular sensing layer comprising of: forming in sequence a molecular sensing layer and a second patterned photo resist layer on the substrate; etching the molecular sensing layer; and removing the second patterned photo resist layer.

More another objective of the present invention is to provide a manufacturing method for CMOS sensor, wherein the second etching process comprising of in sequence an anisotropic etching process to etch the protection layer and an isotropic etching process to etch the substrate.

### BRIEF DESCRIPTION OF THE DRAWINGS

These and other objects, features and advantages of the present invention will become apparent to those skilled in the art upon consideration of the following description of the preferred embodiments of the present invention taken in conjunction with the accompanying drawings, in which:

FIG. 1A˜1I is the flow chart of the manufacturing method of CMOS biosensor of the embodiment of the present invention.

### DETAILED DESCRIPTION OF THE INVENTION

The present invention will be described in the followings by different embodiments, and the components, arrangements and steps used to describe the content of this embodiment are only examples and are not used to limit this invention. In addition, “and/or” used in the disclosed content is for briefing purpose; the descriptions of “covering” or “above” can include the direct contact and no direct contact.

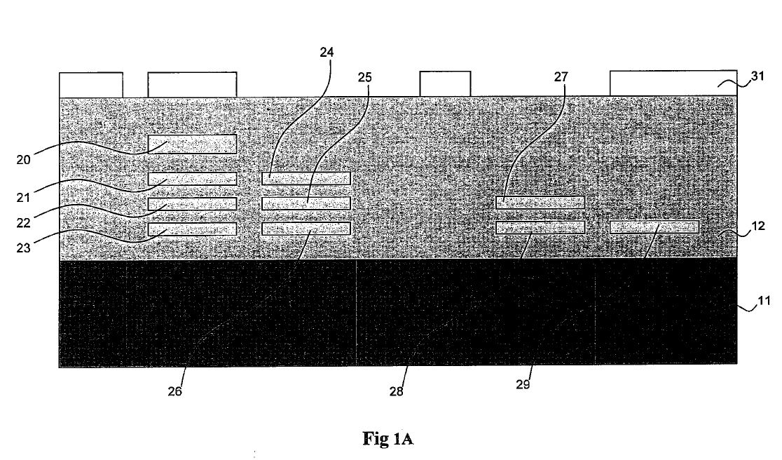

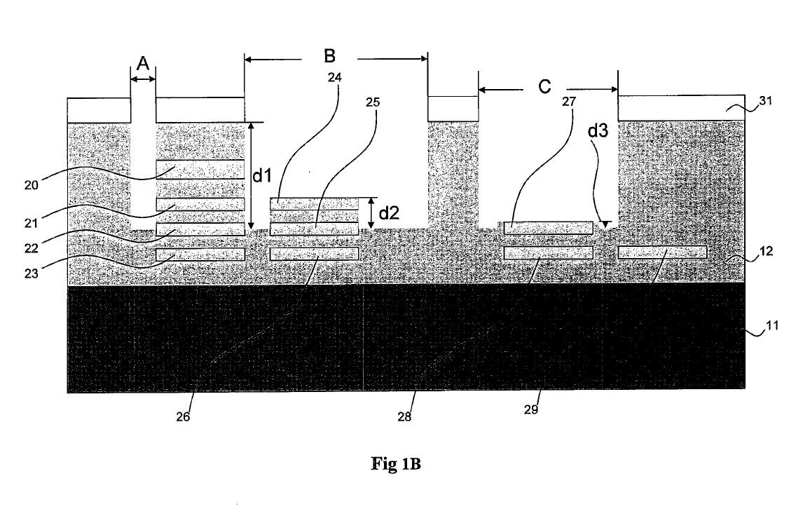

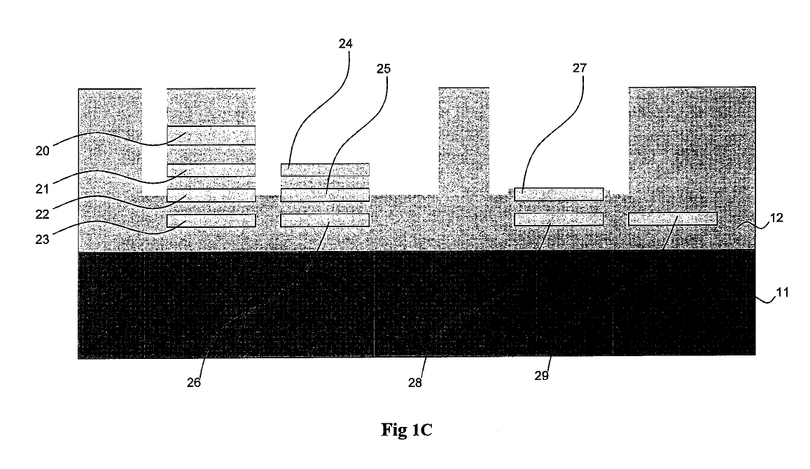

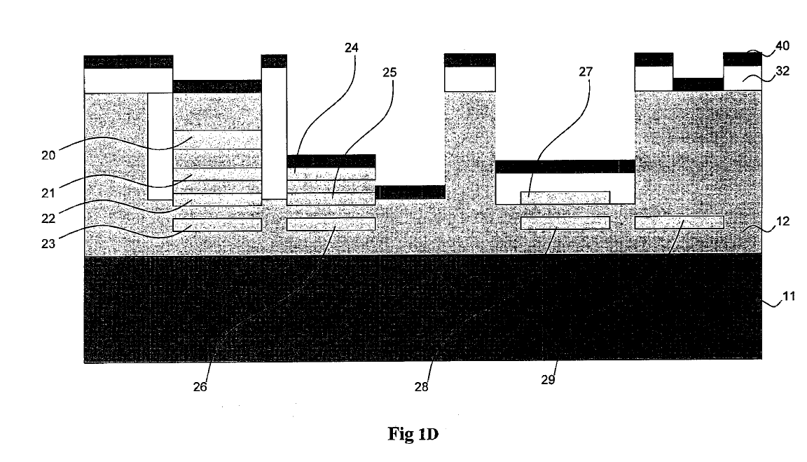

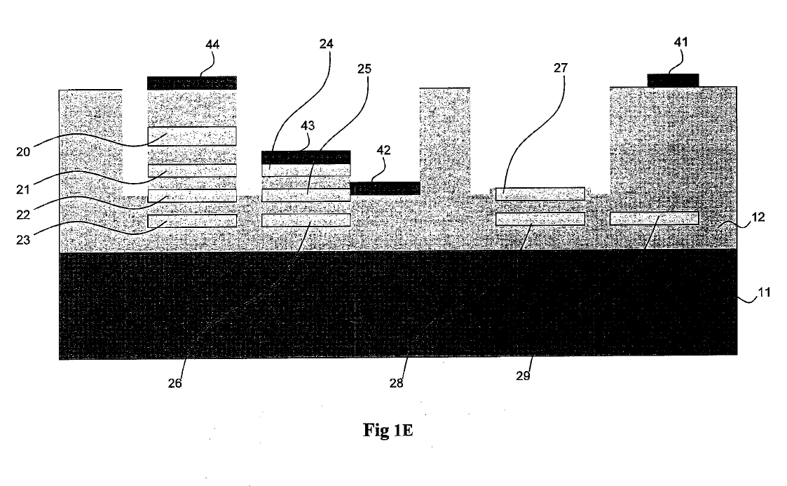

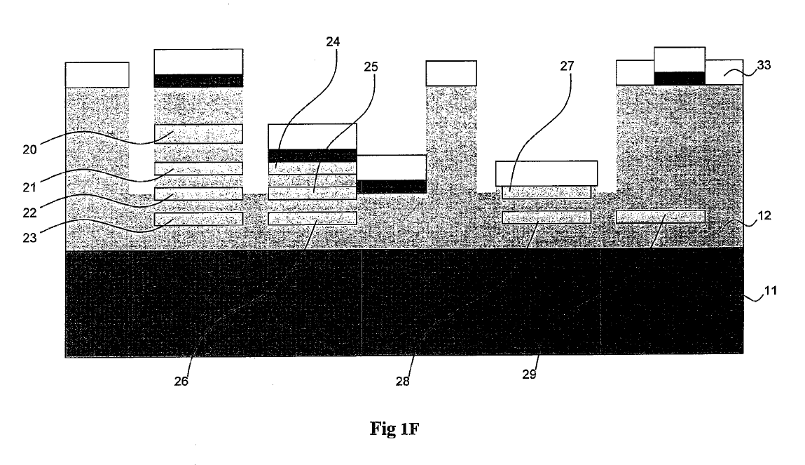

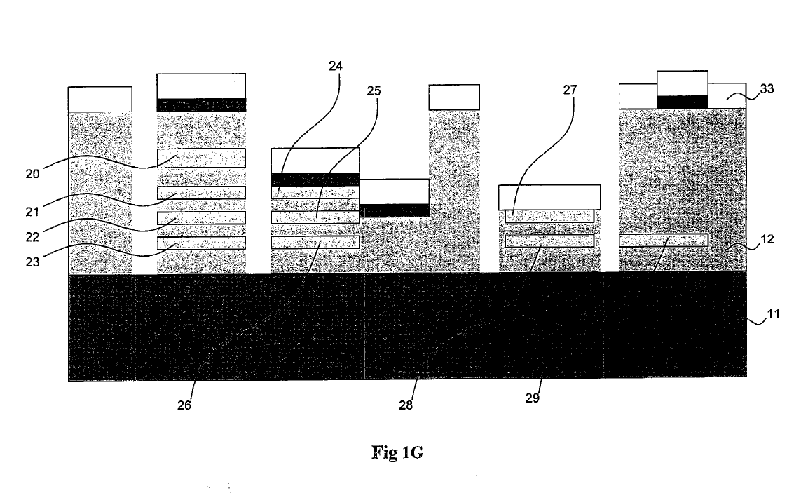

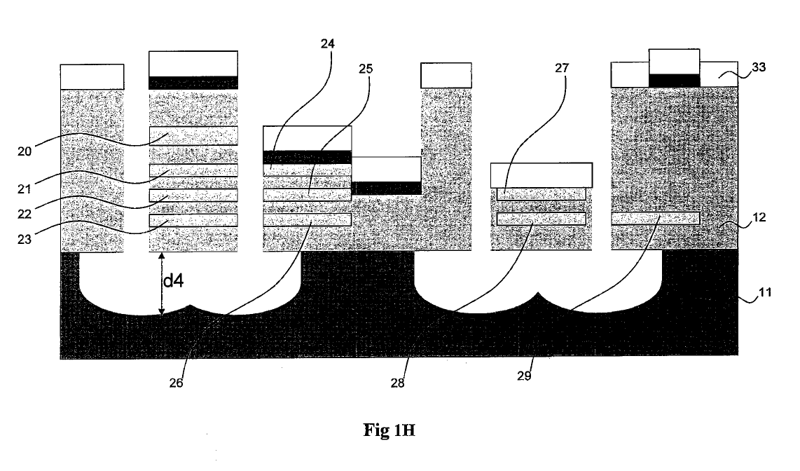

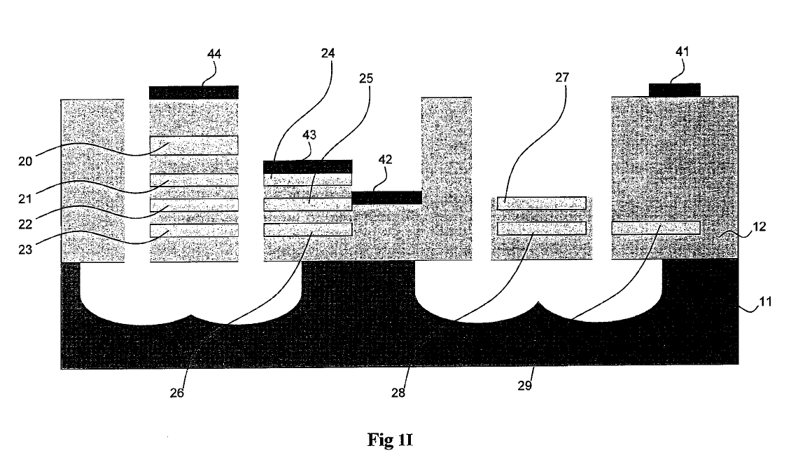

FIG. 1A˜1I shows a flow chart of the manufacture method of CMOS biosensor of the first embodiment of the present invention. FIG. 1A shows, through the use of semiconductor processes such as: Chemical Vapor Deposition (CVD), Physical Vapor Deposition (PVD), Photo Resist Coating, Photolithography, Dry Etching and Wet Etching, the formation of multiple device structural layers such as 20, 21, 22, 23, 24, 25, 26, 27, 28, 29 so as to form CMOS structure and Biosensor structure (not shown in the figure). On the substrate, protection layer 12 and first patterned photo resist layer 31 are formed in sequence. Wherein protection layer 12 are, for example, Silicon Oxide or Silicon Nitride material used to cover substrate 11 and multiple device structural layers 20, 21, 22, 23, 24, 25, 26, 27, 28, 29.

The substrate used here can be silicon substrate of single crystal, poly crystal or amorphous structure; CMOS structure can be all kinds of currently known semiconductor device or system; biosensor structure can include, for example, sensor devices used to detect Deoxyribonucleic Acid (DNA), Protein, Tissue, Cell, Ion, pH value, etc., or different sensor devices designed and manufactured according to other sensor purposes. Therefore, the structure or material of device structural layers 20, 21, 22, 23, 24, 25, 26, 27, 28 and 29 will have different designs according to the need of semiconductor device or system and biosensor structure, for example, the material could be metallic material or poly crystal material, etc.

FIG. 1B˜1C uses first patterned photo resist layer 31 as etching mask so as to facilitate the first etching process of anisotropic etching process such as plasma etching and to etch protection layer 12 to the preset etch stop layer for trenches A, B and C, and then the first patterned photo resist layer 31 is removed. In the current embodiment, since the preset etch stop layer is lower than the device structural layer 24 and 27, and device structure layer 24 and 27 do not have first patterned photo resist layer 31 as mask protection, hence, when trenches B and C are etched to device structural layers 24 and 27, through the selectivity of etching process, device structural layers 24 and 27 will become another etching mask, and the protection layer 12 underneath device structural layer 24 and 27 will not be etched; therefore, there is no need to use special technique or process to obtain protection layer 12 of different thicknesses d1, d2 and d3 after an etching process. What needs to be noticed is, even device structural layer 24 and 27 is used as etch stop layers, as long as the pattern of first patterned photo resist layer 31 is used together and through appropriate selectivity of etching process, the same or similar result can be obtained.

Please refer to FIGS. 1D˜1E; in the chip which is completed with first etch process, second patterned photo resist layer 32 and molecular sensing layer 40 are formed in sequence, wherein molecular sensing layer 40 has material coming from polymer, ceramic material and metals such as: Au, Ag, Pt or its alloys materials which are more sensitive to molecular biology, ion and PH value; the methods of formation of these materials include: spin-coating, deposition, sputtering or electro-plating, etc.; next, photo resist lift-off process is used to remove second patterned photo resist layer and part of the molecular sensing layer 40 on the upper part, and on the structure, only patterned molecular sensing layer 41, 42, 43 and 44 are left.

In addition to the use of photo resist lift-off process method as in FIG. 1D˜1E, other processes can also be used, which are not shown in the figure, and are described as in the followings: forming first on the substrate 11 entirely with molecular sensing layer 40, then forming second patterned photo resist layer 32 and using second patterned photo resist layer 32 as mask to perform etching on molecular sensing layer 40, then removing second patterned photo resist layer 32 to form patterned molecular sensing layer 41, 42, 43 and 44. General processes will need one more etching process on molecular sensing layer 40 as compared to the photo resist lift-off process of FIG. 1D˜1E; however, depending on the actual process design and device requirement, the user can select to use general process or photo resist lift-off process of FIG. 1D˜1E.

Please refer to the process of FIG. 1F˜1I, substrate 11 is formed first with a third patterned mask 33 to expose an area where protection layer 12 is to be etched off, next, an anisotropic etching process such as drying etch process of plasma etch is used to etch the exposed protection layer 12 to expose the surface of substrate 11, then an isotropic etching process is used, for example, the wet etching process, to etch the substrate 11 until the second etch stop is reached so as to remove part of the substrate 11 at the lower part of part of the sensor structural layer, 20, 21, 22, 23, 27 and 28; a gap d4 is then formed and is connected only by the suspension arm structure (not shown in the figure) on the side part, and those sensor structural layers 20, 21, 22, 23, 27 and 28 thus form suspension arm structure.

Although the present invention is disclosed above with better embodiment, yet it is not used to limit the present invention, anyone who is familiar with the prior art, without deviating the spirit and scope of this invention, can make any kind of change, modification and trimming; therefore, the protection scope of this invention should be based on what is claimed as state in the following.

What is claimed is:

1. A manufacture method for complementary metal oxide semiconductor sensor, comprising of:
providing a substrate which contains multiple device structural layer;
forming a protection layer to cover the substrate and those device structural layers;
forming a first patterned photo-resist layer above the substrate;
performing a first etching process to etch the protection layer until a first etch stop,
forming a patterned molecular sensing layer above the substrate;
forming a third patterned photo-resist layer above the substrate; and
performing a second etching process to etch the protection layer and the substrate until a second etch stop so as to remove the substrate part beneath part of those sensor structural layers.

2. The manufacture method for complementary metal oxide semiconductor sensor of claim 1 wherein the material of the substrate is of single crystal silicon.

3. The manufacture method for complementary metal oxide semiconductor sensor of claim 1 wherein the device structural layer comprising of metallic layer, dielectric layer or poly silicon layer.

4. The manufacture method for CMOS sensor of claim 3 wherein the materials of molecular sensing layer are including of gold, silver and platinum. etc. or its alloys.

5. The manufacture method for complementary metal oxide semiconductor sensor of claim 3 wherein the material of the molecular sensing layer can be polymers form, spin-coating, deposition, sputtering or electro-plating.

6. The manufacture method for CMOS sensor of claim 3 wherein the material of the molecular sensing layer can be ceramic materials from depositing or sputtering.

7. The manufacture method for CMOS sensor of claim 1 wherein the materials of protection layer are, for example, silicon dioxide, silicon nitride etc.

8. The manufacture method for CMOS sensor of claim 1 wherein the first etch stop layer is from at least one of those device structural layers.

9. The manufacture method for CMOS sensor of claim 1 wherein at least one of those device structural layers is the etch mask of first etching process.

10. The manufacture method for CMOS sensor of claim 1 wherein the materials of patterned molecular sensing layer are from, for example, metals such as gold, silver and platinum., etc. or its alloys.

11. The manufacture method for CMOS sensor of claim 1 wherein the materials of patterned molecular sensing layer can be polymers from spin-coating, depositing and electro-plating.

12. The manufacture method for CMOS sensor of claim 1 wherein the materials of patterned molecular sensing layer are ceramic materials from depositing or sputtering processes.

13. The manufacture method for CMOS sensor of claim 1 wherein the methods of forming the patterned molecular sensing layer comprising of:
forming in sequence a second patterned photo resist layer and a molecular sensing layer on the substrate; and
removing the second patterned photo resist layer and part of the molecular sensing layer on the top.

14. The manufacture method for CMOS sensor of claim 13 wherein the method of removing the second patterned photo resist layer is a photo resist lift-off process.

15. The manufacture method for CMOS sensor of claim 1 wherein the method of forming patterned molecular sensing layer comprising of:
forming in sequence a molecular sensing layer and a second patterned photo resist layer on the substrate;
etching the molecular sensing layer;
and removing the second patterned photo resist layer.

16. The manufacture method for CMOS sensor of claim 1 wherein the first etching process is an anisotropic etching process.

17. The manufacture method for CMOS sensor of claim 1 wherein the second etching process, comprising of in sequence an anisotropic etching process, which etches until the protection layer, and an isotropic etching process, which etches until the substrate.
